(19) United States
(12) Patent Application Publication
(10) Pub. No.: US 2013/0164687 A1
(43) Pub. Date: Jun. 27, 2013

(54) HYBRID COOLING AND THERMAL SHIELD FOR ELECTROMAGNETIC ACTUATORS

(71) Applicants: Michael B. Binnard, Balmont, CA (US); Scott Coakley, Belmont, CA (US)

(72) Inventors: Michael B. Binnard, Balmont, CA (US); Scott Coakley, Belmont, CA (US)

(21) Appl. No.: 13/538,421

(22) Filed: Jun. 29, 2012

Related U.S. Application Data
(60) Provisional application No. 61/503,095, filed on Jun. 30, 2011.

(51) Int. Cl. H02K 9/00; G03F 7/20; H02K 41/02

(52) U.S. Cl. CPC H02K 9/005; H02K 41/02; G03F 7/2041
USPC 430/322; 310/12.06; 355/30

(57) ABSTRACT

A stage assembly includes a stage, a base assembly, a stage mover, and a temperature adjuster. The temperature adjuster includes a first plate, a first thermal insulator, a circulation housing, a first fluid system, and a second fluid system. The first plate is positioned adjacent to a conductor array of the stage mover. The first thermal insulator is positioned adjacent to the first plate. The circulation housing defines at least a portion of a housing passageway that is positioned adjacent to the first thermal insulator. The first fluid system directs a first circulation fluid through the housing passageway, and the second fluid system directs a second circulation fluid through the first plate channel. With this design, the second circulation fluid removes the majority of the heat from the conductor array, and the first circulation fluid shields an outer surface of the circulation housing from thermal disturbance.

### RELATED APPLICATION

The application claims priority on Provisional Application Ser. No. 61/503,095 filed on Jun. 30, 2011, entitled “HYBRID COOLING AND THERMAL SHIELD FOR ELECTROMAGNETIC ACTUATORS”. As far as is permitted, the contents of U.S. Provisional Application Serial No. 61/503,095 are incorporated herein by reference.

### BACKGROUND

Exposure apparatuses for semiconductor processing are commonly used to transfer images from a reticle onto a semiconductor wafer. A typical exposure apparatus includes an illumination source, a reticle stage assembly that retains a reticle, a lens assembly and a wafer stage assembly that retains a semiconductor wafer. The images transferred onto the wafer from the reticle are extremely small. Accordingly, the precise positioning of the wafer and the reticle is critical to the manufacturing of the wafer. In order to obtain precise relative alignment, the position of the reticle and the wafer are constantly monitored by a measurement system.

Typically, the reticle stage assembly including one or more movers that move and position the reticle, and the wafer stage assembly includes one or more movers that move and position the wafer. Unfortunately, electrical current directed to the movers generates heat that is subsequently transferred to the surrounding environment, including the air surrounding the movers and the other components positioned near the movers. The heat changes the index of refraction of the surrounding air. This reduces the accuracy of the measurement system and degrades machine positioning accuracy. Further, the heat causes expansion of the other components of the machine. This further degrades the accuracy of the machine.

Conventionally, the movers are cooled by forcing a coolant around the movers. However, existing coolant systems do not efficiently cool the movers and as a result allow for heat to be transferred from the movers to the surrounding environment. This reduces the accuracy of positioning of the wafer relative to the reticle, and degrades the accuracy of the exposure apparatus.

### SUMMARY

The present invention is directed to stage assembly that moves a device along a first axis. The stage assembly can include a stage that retains the device, a base assembly, a stage mover that moves the stage, and a temperature adjuster that adjusts the temperature of at least a portion of the stage mover. The stage mover includes a magnet array that is secured to one of the stage and the base assembly, and a conductor array that is secured to the other of the stage and the base assembly. As provided herein, current directed to the conductor array creates a force that can be used to move one of the arrays relative to the other array.

The temperature adjuster includes a first plate, a first thermal insulator, a circulation housing, a first fluid system, and a second fluid system. The first plate is positioned adjacent to a first side of the conductor array, the first plate defining a first plate channel. The first thermal insulator is positioned adjacent to the first plate. The circulation housing defines at least a portion of a housing passageway that is positioned adjacent to the first thermal insulator. The first fluid system directs a first circulation fluid through the housing passageway, the second fluid system directs a second circulation fluid through the first plate channel. With this design, the second circulation fluid removes the majority of the heat from the conductor array, and the first circulation fluid shields an outer surface of the circulation housing from thermal disturbance.

In one embodiment, the circulation housing encircles the first plate, the first thermal insulator, and at least a portion of the conductor array. Further, the temperature adjuster can include (i) a second plate positioned adjacent to a second side of the conductor array, the second plate defining a second plate channel, and (ii) a second thermal insulator positioned adjacent to the second plate; wherein the second fluid system directs the second circulation fluid through the second plate channel.

In another embodiment, the conductor array can include a first conductor unit and a second conductor unit, and the temperature adjuster can include a separate first plate and a separate first thermal insulator for the first conductor unit and the second conductor unit. Further, the circulation housing can include a separate surface housing for the first conductor unit and the second conductor unit.

As provided herein, the problem of removing heat from stage mover without creating unacceptable thermal disturbances is solved by using high-pressure cold-plate cooling and a high temperature rise to remove the majority of the heat from the coils, and surrounding the exterior of the cold-plates with a low pressure conventional cooling jacket to shield the exterior of the stage mover from thermal disturbances caused by the large temperature rise.

The present invention is also directed to an exposure apparatus, a device manufactured with the exposure apparatus, and/or a wafer on which an image has been formed by the exposure apparatus. Further, the present invention is also directed to a method for making a stage assembly, a method for making an exposure apparatus, a method for making a device and a method for manufacturing a wafer.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a perspective view of a stage assembly and a control system having features of the present invention;

FIG. 2A is a cut-away view taken on line 2A-2A in FIG. 1;

FIG. 2B is an exploded perspective view of a first conductor unit and a portion of a temperature adjuster having features of the present invention;

FIG. 2C is an exploded perspective view of a second conductor unit and a portion of the temperature adjuster having features of the present invention;

FIG. 3A is a cut-away view of another embodiment of a conductor array and a temperature adjuster having features of the present invention;

FIG. 3B is an exploded perspective view of another embodiment of a first conductor unit and a portion of a temperature adjuster having features of the present invention;

FIG. 4 is an exploded perspective view of yet another embodiment of a first conductor unit and a portion of a temperature adjuster having features of the present invention;

FIG. 5 is a cut-away view of another embodiment of a conductor array and a temperature adjuster having features of the present invention;

FIG. 6A is a perspective view of another embodiment of a stage assembly having features of the present invention;

FIG. 6B is an exploded perspective view of yet another embodiment of a conductor unit and a portion of a temperature adjuster having features of the present invention;

FIG. 7A is a perspective view of still another embodiment of a stage assembly having features of the present invention;

FIG. 7B is a cut-away view taken on line 7B-7B in FIG. 7A; FIG. 8A is a perspective view of yet another embodiment of a stage assembly having features of the present invention;

FIG. 8B is a cut-away view taken on line 8B-8B in FIG. 8A;

FIG. 9 is a schematic illustration of an exposure apparatus having features of the present invention;

FIG. 10A is a flow chart that outlines a process for manufacturing a device in accordance with the present invention; and

FIG. 10B is a flow chart that outlines device processing in more detail.

### DESCRIPTION

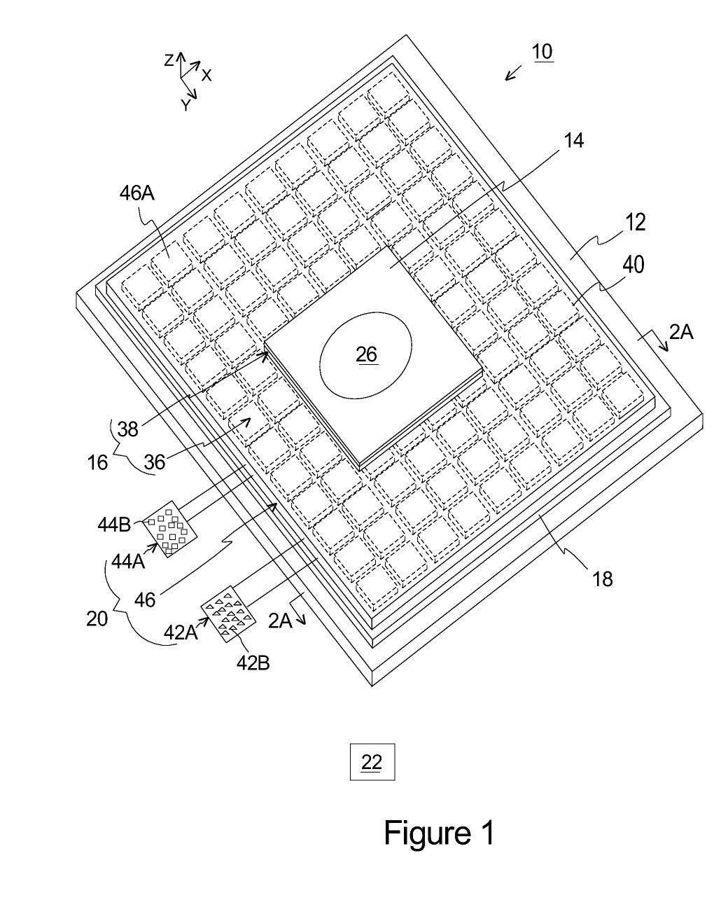

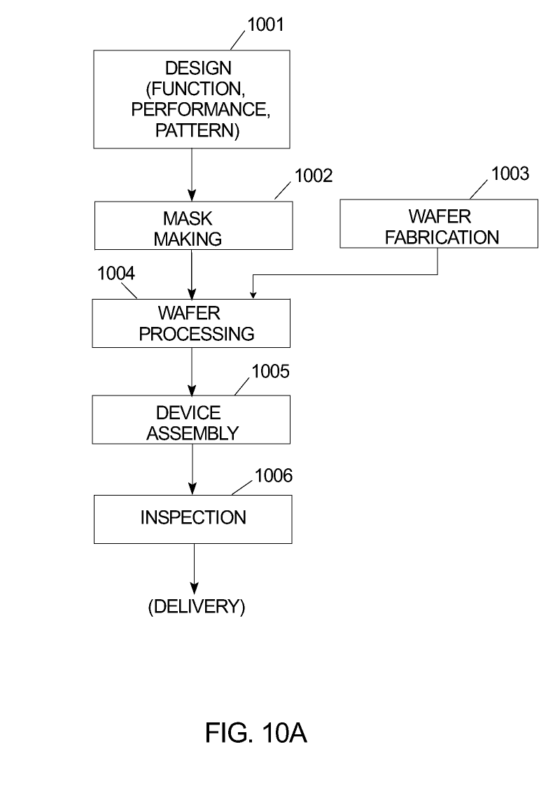

Referring initially to FIG. 1, a stage assembly 10 having features of the present invention includes a stage base 12, a stage 14, a stage mover 16, a base assembly 18, a temperature adjuster 20, and a control system 22. The design of each of these components can be varied to suit the design requirements of the assembly 10. The stage assembly 10 can be positioned above a mounting base 924 (illustrated in FIG. 9). The stage mover 16 precisely moves the stage 14 relative to the stage base 12 and the base assembly 18. It should be noted that the stage assembly 10 can be designed with more or fewer components than that illustrated in FIG. 1.

As an overview, in certain embodiments, the stage mover 16 and the temperature adjuster 20 are uniquely designed and controlled to efficiently maintain a substantially uniform temperature of a portion of the temperature adjuster 20 and/or the base assembly 18. This can reduce the amount of heat transferred from the stage mover 16 to the surrounding environment. With this design, the stage mover 16 can be placed closer a measurement system (not shown in FIG. 1) used to monitor the position of the stage 14, and/or the influence of the stage mover 16 on the accuracy of the measurement system is reduced. As a result thereof, the stage assembly 10 can position the stage 14 with improved accuracy.

The stage assembly 10 is particularly useful for precisely positioning a device 26 during a manufacturing and/or an inspection process. The type of device 26 positioned and moved by the stage assembly 10 can be varied. For example, the device 26 can be a semiconductor wafer, and the stage assembly 10 can be used as part of an exposure apparatus 930 (illustrated in FIG. 9) for precisely positioning the semiconductor wafer during manufacturing of the semiconductor wafer. Alternately, for example, the device 26 can be a reticle, and the stage assembly 10 can be used for precisely positioning the reticle during manufacturing of a semiconductor wafer. Still alternatively, the stage assembly 10 can be used to move other types of devices during manufacturing and/or inspection, to move a device under an electron microscope (not shown), or to move a device during a precision measurement operation (not shown).

Some of the Figures provided herein include an orientation system that designates an X axis, a Y axis, and a Z axis. It should be understood that the orientation system is merely for reference and can be varied. For example, the X axis can be switched with the Y axis and/or the stage assembly 10 can be rotated. Moreover, these axes can alternatively be referred to as a first, second, or third axis.

The stage base 12 supports a portion of the stage assembly 10 above the mounting base 924. In the embodiment illustrated herein, the stage base 12 is rigid and is generally rectangular plate shaped, although other shapes and configurations of the stage base 12 are possible.

The stage 14 retains the device 26. The stage 14 is precisely moved by the stage mover 16 to precisely position the device 26. In one embodiment, the stage 14 is generally rectangular shaped and includes a device holder (not shown) for retaining the device 26. The device holder can be a vacuum chuck, an electrostatic chuck, or some other type of clamp. In the embodiments illustrated herein, the stage assembly 10 includes a single stage 14 that is moved relative to the stage base 12. Alternatively, for example, the stage assembly 10 can be designed to include multiple stages that are independently moved relative to the stage base 12.

The stage mover 16 controls and adjusts the position of the stage 14 and the device 26 relative to the base assembly 18 and the stage base 12. For example, the stage mover 16 can be a planar motor that moves and positions of the stage 14 with six degrees of freedom (e.g. along the X, Y, and Z axes, and about the X, Y, and Z axes). Alternatively, the stage mover 16 can be designed to move the stage 14 with fewer than six degrees of freedom. For example, the stage 14 can be maintained along the Z axis with a vacuum preload type fluid bearing or another type of bearing and the stage mover 16 can move the stage 14 with three degrees of freedom (e.g. along the X axis, along the Y axis, and about the Z axis).

In one embodiment, the stage mover 16 is an electromagnetic actuator that includes a conductor array 36 (illustrated in phantom) and a magnet array 38 (illustrated as a box). One of the arrays 36, 38 is secured to the top of the base assembly 18 and the other array 36, 38 is secured to the bottom of the stage 14. In FIG. 1, the conductor array 36 is secured to the top of the base assembly 18, and the magnet array 38 is secured to the bottom of the stage 14. Alternatively, the magnet array 38 can be secured to the top of the base assembly 18, and the conductor array 36 can be secured to the bottom of the stage 14.

In FIG. 1, the conductor array 36 includes a plurality of conductor units 40 (illustrated in phantom as rectangular boxes) that are arranged in a rectangular shaped grid. The number of conductor units 40 in the conductor array 36 can be varied to suit the movement requirements of the stage mover 16. In the simplified example illustrated in FIG. 1, the conductor array 36 includes one hundred and eight conductor units 40 that are secured to the base assembly 18 and that are arranged in a twelve by nine grid. Alternatively, the conductor array 36 can be designed to include more than or fewer than one hundred and eight separate conductor units 40.

The magnet array 38 includes a plurality of magnets. The size, shape and number of magnets can be varied to suit the design requirements of the stage mover 16. Each magnet can be made of a permanent magnetic material such as NdFeB.

Electrical current (not shown) is independently supplied to the conductor units 40 by the control system 22. The electrical current in the conductor units 40 interact with the magnetic field(s) of the one or more magnets in the magnet array 38. This causes a force (Lorentz type force) between the conductor units 40 and the magnets that can be used to move the stage 14 relative to the stage base 12.

Unfortunately, the electrical current supplied to the conductor array 36 also generates heat, due to resistance in the conductor array 36. Moreover, the resistance of the conductor array 36 increases as temperature increases. This exacerbates the heating problem and reduces the performance and life of the stage mover 16. Heat transferred to the base assembly 18 can cause expansion and distortion. Further, heat transferred to the surrounding environment can adversely influence the measurement system. In certain embodiments, the temperature adjuster 20 provided herein efficiently removes the heat and inhibits the transfer of the heat to the base assembly 18 and the surrounding environment.

The base assembly 18 can be any structure, and in certain embodiments, the base assembly 18 receives the reaction forces generated by the stage mover 16. In certain embodiments, the base assembly 18 is a reaction assembly that counteracts, reduces and minimizes the influence of the reaction forces from the stage mover 16 on the position of the stage base 12. Further, this allows for more accurate positioning of the stage 14. As provided above, the conductor array 36 of the stage mover 16 is coupled to the base assembly 18. With this design, the reaction forces generated by the stage mover 16 are transferred to the base assembly 18. When the stage mover 16 applies a force to move the stage 14, an equal and opposite reaction force is applied to the base assembly 18. In FIG. 1, the base assembly 18 is a rigid, rectangular shaped countermass that is maintained above the stage base 12 with a reaction bearing (not shown), e.g. a vacuum preload type fluid bearing that allows for motion of the countermass base assembly 18 relative to the stage base 12 along the X axis, along the Y axis and about the Z axis. Alternately, for example, the reaction bearing can be a magnetic type bearing, or a roller bearing type assembly.

With this design, (i) movement of the stage 14 with the stage mover 16 along the X axis, generates an equal and opposite X reaction force that moves the countermass base assembly 18 in the opposite direction along the X axis; (ii) movement of the stage 14 with the stage mover 16 along the Y axis, generates an equal and opposite Y reaction force that moves the countermass reaction assembly 18 in the opposite direction along the Y axis; and (iii) movement of the stage 14 with the stage mover 16 about the Z axis generates an equal and opposite theta Z reaction moment (torque) that moves the countermass base assembly 18 about the Z axis.

In certain embodiments, the ratio of the mass of the countermass reaction assembly 18 to the mass of the stage 14 is relatively high. This will minimize the movement of the countermass base assembly 18 and minimize the required travel of the countermass base assembly 18. A suitable ratio of the mass of the countermass base assembly 18 to the mass of the stage 14 is between approximately 2:1 and 10:1. In one embodiment, the countermass base assembly 18 comprises components made from a non-electrically conductive, non-magnetic material, such as low electrical conductivity stainless steel or titanium, or non-electrically conductive plastic or ceramic.

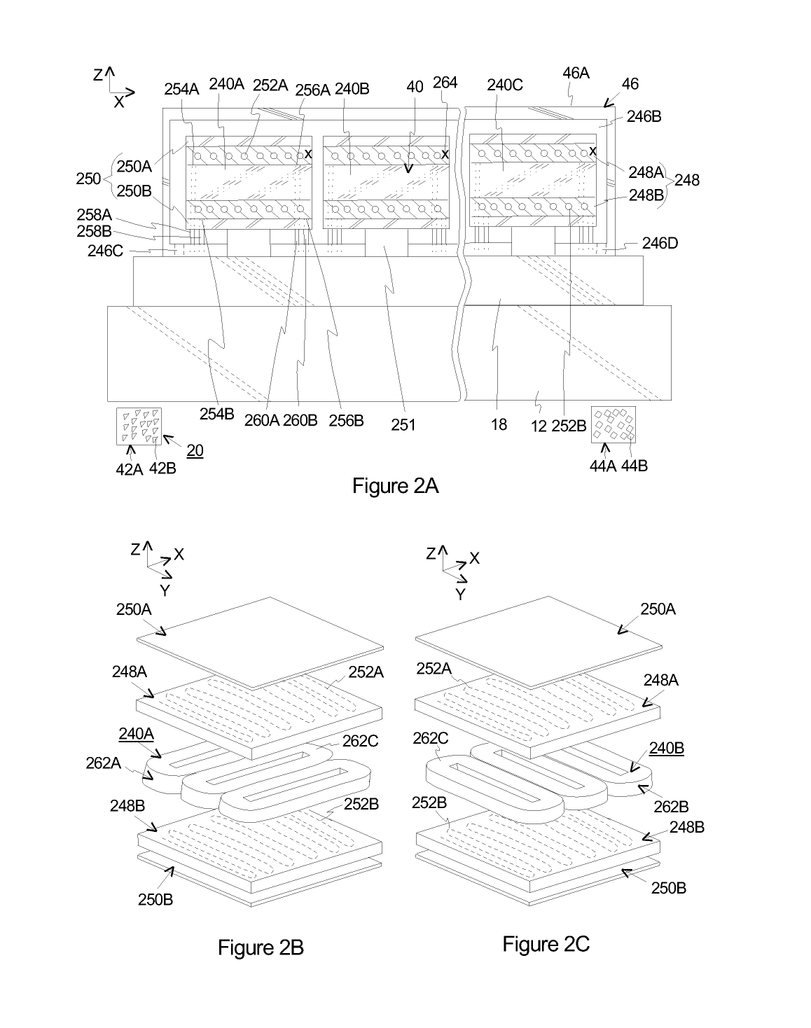

The temperature adjuster 20 can be used to reduce the influence of the heat from the conductor array 36 from adversely influencing the other components of the stage assembly 10. The design of the temperature adjuster 20 can vary. In one embodiment, the temperature adjuster 20 includes (i) a first fluid system 42A (illustrated as a box), (ii) a second fluid system 44A (illustrated as a box), (iii) a circulation housing 46, (iv) a plate assembly 248 (illustrated in FIG. 2A), and (v) an insulation assembly 250 (illustrated in FIG. 2A). The design of each of these components can vary pursuant to the teachings provided herein. As provided herein, the circulation housing 46 encircles a portion or all of (i) the conductor units 40, (ii) the plate assembly 248, and/or (iii) the insulation assembly 250. For example, in FIG. 1, the circulation housing 46 encircles all of (i) the conductor units 40, (ii) the plate assembly 248, and/or (iii) the insulation assembly 250.

Further, as provided herein, (i) the first fluid system 42A directs a first circulation fluid 42B (illustrated as small triangles) into the circulation housing 46 to maintain the temperature of an outer surface 46A of the circulation housing 46 at a predetermined temperature, (ii) the second fluid system 44A directs a second circulation fluid 44B (illustrated as small squares) through the plate assembly 248 to remove the bulk of the heat created by the conductor units 40, and (iii) the insulation assembly 250 reduces the amount of heat transferred from the plate assembly 248 to the first circulation fluid 42B. With this design, the temperature of the outer surface 46A of the circulation housing 46 is easier to maintain at the predetermined temperature.

Each fluid system 42A, 44A can include one or more pumps, reservoirs, heat exchanges, chillers, pressure controllers, manifolds, and/or valves.

Further, the type of circulation fluid 42B, 44B can be varied. For example, each circulation fluid 42B, 44B can be water. In another embodiment, the composition of the circulation fluids 42B, 44B can be different. For example, the specific heat of the first circulation fluid 42B can be different from that of the second circulation fluid 44B. In alternative embodiments, the specific heat of the first circulation fluid 42B can be greater or smaller than the specific heat of the second circulation fluid 44B. Additionally, the thermal conductivity of the first circulation fluid 42B can be greater or smaller than the thermal conductivity of the second circulation fluid 44B. As an example, the first circulation fluid 42B can be Fluorinert and the second circulation fluid 44B can be water. In this example embodiment, the high specific heat of water allows the second circulation fluid 44B to remove a larger amount of heat for a corresponding change in the fluid temperature. The low thermal conductivity of Fluorinert reduces the heat transfer through the first circulation fluid 42B to the circulation housing 46.

In certain embodiments, the circulation fluid 42B, 44B can be referred to as a coolant.

The control system 22 is electrically connected to, directs and controls electrical current to the conductor array 36 of the stage mover 16 to precisely position the device 26. Further, the control system 22 is electrically connected to and controls (i) the first circulation system 42A to control the temperature, flow rate and pressure of the first circulation fluid 42B directed into the circulation housing 46, (ii) the second circulation system 44A to control the temperature, flow rate and pressure of the second circulation fluid 44B directed into the plate assembly 248. This allows the control system 22 to accurately control the temperature of the circulation housing 46. The control system 22 can include one or more processors and circuits.

FIG. 2A is a cut-away view taken on line 2A-2A in FIG. 1 illustrating (i) a portion of the stage base 12, (ii) a portion of the base assembly 18, (iii) three conductor units 40, and (iv) a portion of the temperature adjuster 20. In this embodiment, moving left to right, the conductor units 40 can be referred to a first conductor unit 240A, a second conductor unit 240B, and a third conductor unit 240C for ease of discussion. Additionally, each conductor unit 240A, 240B, 240C includes opposed sides. Moreover, in this embodiment, each conductor unit 40 includes a separate attachment beam 251 that fixedly secures the respective conductor unit 40 to the base assembly 18.

FIG. 2A illustrates one non-exclusive embodiment of the temperature adjuster 20. In this embodiment, the temperature adjuster 20 includes the plate assembly 248, the insulation assembly 250, the circulation housing 46, and the fluid systems 42A, 44A. In the embodiment illustrated in FIG. 2A, for each conductor unit 40, (i) the plate assembly 248 includes an upper, first plate 248A, and a lower, second plate 248B that are positioned on opposite sides of the conductor unit 40; and (ii) the insulation assembly 250 includes an upper, first thermal insulator 250A positioned on top of the first plate 248A, and a lower, second thermal insulator 250B positioned below the second plate 248B. With this design, the insulation assembly 250 inhibits the transfer of heat from the plate assembly 248 to the first circulation fluid 42B. Each plate 248A, 248B can also be referred to as a cold plate.

Alternatively, in certain embodiments, the temperature adjuster 20 can be designed without the upper plate(s) 248A, the lower plate(s) 248B, the upper insulator(s) 250A, and/or the lower insulator(s) 250B.

In FIG. 2A, the first plate 248A includes (i) one or more first plate channels 252A (illustrated with circles) that weave back and forth in a serpentine pattern in the first plate 248A, (ii) a first plate inlet 254A that is in fluid communication with the first plate channel(s) 252A, and (iii) a first plate outlet 256A that is also in fluid communication with the first plate channel(s) 252A. Similarly, the second plate 248B includes (i) one or more second plate channels 252B (illustrated with circles) that weave back and forth in a serpentine pattern in the second plate 248B, (ii) a second plate inlet 254B that is in fluid communication with the second plate channel(s) 252B, and (iii) a second plate outlet 256B that is also in fluid communication with the second plate channel(s) 252B. In non-exclusive alternative embodiments, other flow patterns for the channels 252A, 252B may be preferable, such as a single channel or a group of parallel channels making one pass across the plates 248A, 248B.

In FIG. 2A, the second fluid system 44A (i) is in fluid communication with the first plate inlet 254A and the first plate outlet 256A of each first plate 248A so that the second fluid system 44A can selectively direct the second circulation fluid 44B through the first plate channel 252A for each conductor unit 40 in a re-circulating fashion; and (ii) is in fluid communication with the second plate inlet 254B and the second plate outlet 256B of each second plate 248B so that the second fluid system 44A can selectively direct the second circulation fluid 44B through the second plate channel 252B for each conductor unit 40 in a re-circulating fashion.

In this embodiment, for each conductor unit 40, the assembly includes (i) a first inlet tube 258A that connects the first plate inlet 254A in fluid communication with the second fluid system 44A, (ii) a second inlet tube 258B that connects the second plate inlet 254B in fluid communication with the second fluid system 44A, (iii) a first outlet tube 260A that connects the first plate outlet 256A in fluid communication with the second fluid system 44A, and (iv) a second outlet tube 260B that connects the second plate outlet 256B in fluid communication with the second fluid system 44A.

In one embodiment, each plate 248A, 248B is rigid and rectangular plate shaped. Further, in this embodiment, each plate channel 252A, 252B is a micro-channel (e.g. a very small channel). With this design, the second fluid system 44A can direct the second circulation fluid 44B into the plates 248A, 248B are at high pressure and a high flow rate without distorting the plates 248A, 248B. This feature allows the second fluid system 44A to remove the bulk of the heat from the conductor units 40. As non-exclusive examples, the pressure in each plate channel 252A, 252B can be between approximately ten psi and fifteen psi, and/or the flow rate in each plate channel 252A, 252B can be between approximately thirty psi and fifty psi.

Further, because, the insulation assembly 250 inhibits the transfer of heat from the plate assembly 248 to the first circulation fluid 42B, the temperature of the plate assembly 248 can be very different from the temperature of the first circulation fluid 42B without adversely influencing the temperature of the outer surface 46A. As a result thereof, the second circulation fluid 44B traveling through the plate assembly 248 can experience a relatively large temperature increase (delta T) without adversely influencing the temperature of the outer surface 46A. As a non-exclusive example, the change in temperature from the plate inlet 254A, 254B to the plate outlet 256A, 256B for one or more of the plates 248A, 248B can be between five and fifteen degrees. With this design, the plates 248A, 248B are very efficient in removing heat, particularly if a large delta T is used.

In one embodiment, the circulation housing 46 defines (i) the outer surface 46A that faces the magnet array 38 (illustrated in FIG. 1) and the base assembly 18, and (ii) an inner housing passageway 246B that is positioned between the insulation assembly 250 and the outer surface 46A. As provided herein, the circulation housing 46 can encircle one or more of the conductor units 40, a portion or all of the plate assembly 248, and/or a portion or all of the insulation assembly 250. In FIG. 2A, the circulation housing 46 is shaped like a rectangular box that encircles and encloses all of the conductor units 40, the plate assembly 248, and the insulation assembly 250. Alternatively, multiple circulation housings (not shown in FIG. 2A) can be utilized, with each circulation housing encircling one or more conductor units, or being positioned near one or more conductor units.

In one embodiment, the circulation housing 46 can be made of a rigid, non-electrically conductive, non-magnetic material, such as titanium, or non-electrically conductive plastic or ceramic.

Further, in FIG. 2A, the circulation housing 46 includes a housing inlet 246C and a housing outlet 246D that are in fluid communication with the first fluid system 42A. With this design, the first fluid system 42A can circulate the first circulation fluid 42B through the housing passageway 246B to maintain the desired temperature of the outer surface 46A. Stated in another fashion, in this embodiment, the first fluid system 42A is used to maintain at least a portion of the outer surface 46A at the desired predetermined set temperature. As a non-exclusive embodiment, the predetermined temperature is approximately equal to room temperature and can be approximately equal to twenty-two degrees Celsius. With this design, the temperature adjuster 20 inhibits the transfer of heat from the conductor units 40 to the surrounding environment. This reduces the influence of the conductor units 40 on the temperature of the surrounding components and allows for more accurate positioning of the stage 14.

With the present design, the first circulation fluid 42B flowing in the circulation housing 46 removes very little heat and provides a thermal shield for outer surface 46. With this design, the first fluid system 42A can direct the first circulation fluid 42B into the housing passageway 246B at relatively low pressure and a relatively low high flow rate. As a result thereof, the circulation housing 46 is easier to support and bulging is minimized. As non-exclusive examples, the pressure in the circulation housing 46 can be between approximately three psi and five psi, and/or the flow rate in the circulation housing 46 can be between approximately five liters/minute and twenty liters/minute.

Further, with this design, because the first circulation fluid 42B removes very little heat, the first circulation fluid 42B traveling through the circulation housing 46 will experience very little temperature increase (delta T). With this design, the temperature of the first circulation fluid 42B at the housing inlet 246C can be controlled to be approximately equal to the predetermined desired temperature. As a non-exclusive example, the change in temperature of the first circulation fluid 42B from the housing inlet 246C to the housing outlet 246D can be less than approximately one degree. With this small delta T, there is only a very minimal thermal gradient on the outer surface 46A, and very minimal thermal distortion.

As non-exclusive examples, (i) the pressure of the first circulation fluid 42B at the housing inlet 246C can be approximately 10, 20, 30, or 50 percent less than the pressure of the second circulation fluid 44B at the plate inlets 254A, 254B; (ii) the flow rate of the first circulation fluid 42B can be approximately 10, 20, 30, or 50 percent less than the flow rate of the second circulation fluid 44B; (iii) the delta T of the first circulation fluid 42B can be approximately 50, 70, 90, or 99 percent less than the delta T of the second circulation fluid 44B; and/or (iv) the temperature of the first circulation fluid 42B at the housing inlet 246C can be approximately 0, 1, 5, or 10 degrees more than the temperature of the second circulation fluid 44B at the plate inlets 254A, 254B.

In one, non-exclusive embodiment, the temperature of the first circulation fluid 42B at the housing inlet 246C is approximately equal to a room temperature of the room in which the mover combination 326 is located and the temperature of the second circulation fluid 44B at the plate inlets 254A, 254B is at least approximately ten degrees Celsius less.

As provided herein, the problem of removing heat from the conductor units 40 without creating unacceptable thermal disturbances is solved by using high-pressure cold-plate 248A, 248B cooling and a high temperature rise to remove the majority of the heat from the conductor units 40; and surrounding the exterior of the cold-plates 248A, 248B with a low pressure cooling jacket 46 to shield the exterior 46A of the motor from thermal disturbances caused by the large temperature rise.

As provided herein, in one embodiment, the second fluid system 44A can direct the second circulation fluid 44B into each plate 248A, 248B of each conductor unit 240A, 240B, 240C at approximately the same pressure and approximately at the same temperature. Alternatively, the second fluid system 44A can be designed to direct the second circulation fluid 44B into each plate 248A, 248B of each conductor unit 240A, 240B, 240C at a different pressure and/or different temperature. With this design, the second fluid system 44A can be controlled by the control system 22 (illustrated in FIG. 1) to selectively and individually control the flow rate and/or temperature of the second circulation fluid 44B to each plate 248A, 248B depending upon the amount of heat generated by the respective conductor unit 240A, 240B, 240C. Thus, as one example, during operation of the stage mover 16, if the second conductor unit 240B generates more heat than the first conductor unit 240A, the second fluid system 44A can selectively direct proportionately more of the second circulation fluid 44B to the second conductor unit 240B than the first conductor unit 240A.

Stated in another fashion, the flow rate and/or temperature of the second circulation fluid 44B can be individually adjusted (as needed based on the power consumption) to remove the majority of the heat from each conductor units 240A, 240B, 240C. Further, the first circulation fluid 42B can be used as a thermal shield to maintain the outer surface 46A to inhibit the transfer of heat from each conductor unit 240A, 240B, 240C.

Additionally, in one embodiment, each conductor unit 240A, 240B, 240C can include one or more feedback elements 264 (represented with an “x” in FIG. 2A) that provide feedback to the control system 22 for controlling the temperature adjuster 20. A non-exclusive example of a suitable feedback element 264 is a temperature sensor such as a thermocouple or thermistor.

FIG. 2B is an exploded perspective view of (i) the first conductor unit 240A; (ii) the upper, first plate 248A for the first conductor unit 240A, (iv) the lower, second plate 248B for the first conductor unit 240A; (v) the upper, first insulator 250A for the first conductor unit 240A; and (vi) the lower, second insulator 250B for the first conductor unit 240A. Somewhat similarly, FIG. 2C is an exploded perspective view of (i) the second conductor unit 240B; (ii) the upper, first plate 248A for the second conductor unit 240B, (iv) the lower, second plate 248B for the second conductor unit 240B; (v) the upper, first insulator 250A for the second conductor unit 240B; and (vi) the lower, second insulator 250B for the second conductor unit 240B. The other conductor units in the conductor array can be somewhat similar to the conductor units 240A, 240B illustrated in FIGS. 2B and 2C. Alternatively, the other conductor units can have a different design than that illustrated in FIGS. 2B and 2C.

In this non-exclusive embodiment, the first conductor unit 240A includes a single, first coil set 262A, and the second conductor unit 240B includes a single, second coil set 262B. The design of each coil set 262A, 262B can be varied to suit the design requirements of the stage mover. For example, each coil set 262A, 262B can include one or more conductors 262C. For a three phase linear or planar motor, each coil set 262A, 262B preferably includes three adjacent racetrack shaped conductors 262C (e.g. coils). In one embodiment, (i) the first coil set 262A can also be referred to as a Y coil set because current directed to the first coil set 262A is used to generate a force along the Y axis; and (ii) the second coil set 262B can be referred to as an X coil set because current directed to the second coil set 262B is used to generate a force along the X axis. Each conductor 262C can be made of metal such as copper or any substance or material responsive to electrical current and capable of creating a magnetic field. Each conductor 262C can be made of wire encapsulated in an epoxy or another insulating polymer.

In this embodiment, each plate 248A, 248B is a rigid, generally rectangular plate shaped, and is sized to approximately cover the respective conductor unit 240A, 240B. Alternatively, each plate 248A, 248B can be sized and shaped to cover only a portion of the conductor unit 240A, 240B, or each plate 248A, 248B can be sized and shaped to cover multiple conductor units 240A, 240B. As a non-exclusive example, each plate 248A, 248B can have a thickness of approximately six hundred microns. Stated in another fashion, each plate 248A, 248B can have thickness of between approximately 300 and 1500 microns. Non-exclusive examples of suitable materials for the plates 248A, 248B include copper, titanium, stainless-steel or other materials with thermal, electrical, magnetic, and mechanical properties suitable for a particular application.

As provided above, each plate 248A, 248B includes the micro channel 252A, 252B (illustrated in phantom) that weaves back and forth within the respective plate 248A, 248B. For example, each plate 248A, 248B can be made by welding two half plates together. In this example, for each plate 248A, 248B, each half plate can include a portion of the channel etched into the half plate. Subsequently, for each plate 248A, 248B, the half plates can be assembled to create the micro channels 252A, 252B. As a non-exclusive embodiment, each micro channel 252A, 252B can have cross-section dimensions (perpendicular to the fluid flow) of approximately a few microns wide up to a few hundreds of microns in the Z direction and between one and twenty millimeters in the XY plane. Stated in another fashion, each micro channel 252A, 252B can have a cross-section area (perpendicular to the direction of fluid flow) of between approximately 0.01 and 5 square millimeters. Stated in yet another fashion, each micro channel 252A, 252B can have a cross-section area of less than approximately 0.01, 0.05, 0.1, 0.5, 1, 2, 3, 4, or 5 square millimeters

Further, in this embodiment, each thermal insulator 250A, 250B is generally rectangular plate shaped and is sized to approximately cover the respective plate 248A, 248B. Alternatively, each insulator 250A, 250B can be sized and shaped to cover only a portion of the respective plate 248A, 248B, or each insulator 250A, 250B can be sized and shaped to cover multiple plates 248A, 248B, or each insulator 250A, 250B can be larger than the respective plate 248A, 248B. Each thermal insulator 250A, 250B can be made of a material that is a good thermal insulator (has low coefficient of thermal transfer). With this design, the insulator 250A, 250B inhibits hot or cold portions of the plates 248A, 248B from adversely influencing the temperature of the first circulation fluid 42B and the temperature of the outer surface 46A. As a non-exclusive example, each plate insulator 250A, 250B can have thickness of between approximately one and one thousand microns. Suitable materials for the thermal insulators 250A, 250B include materials having a relatively low coefficient of heat transfer. As a non-exclusive example, the thermal insulators 250A, 250B can have a coefficient of heat transfer of less than approximately one Watt/meter-Kelvin. Non-exclusive examples of suitable materials for the thermal insulators 250A, 250B include plastic, carbon fiber or fiberglass composite, or a closed-cell foam material such as aerogel.

Moving from the bottom to the top in FIGS. 2B and 2C, the assembled components are as follows, (i) the bottom insulator 250B, (ii) the bottom plate 248B that is positioned on top of and in contact with the bottom insulator 250B, (iii) the first conductor unit 240A (FIG. 2B) or the second conductor unit 240B (FIG. 2C) positioned on, adjacent to, and in direct thermal contact with the bottom plate 248B, (iv) the upper plate 248A that is positioned on top of, adjacent to, and in direct thermal contact with the respective conductor unit 240A, 240B, and (v) the upper insulator 250A that is position on top of, adjacent to, and in direct thermal contact with the upper plate 248A.

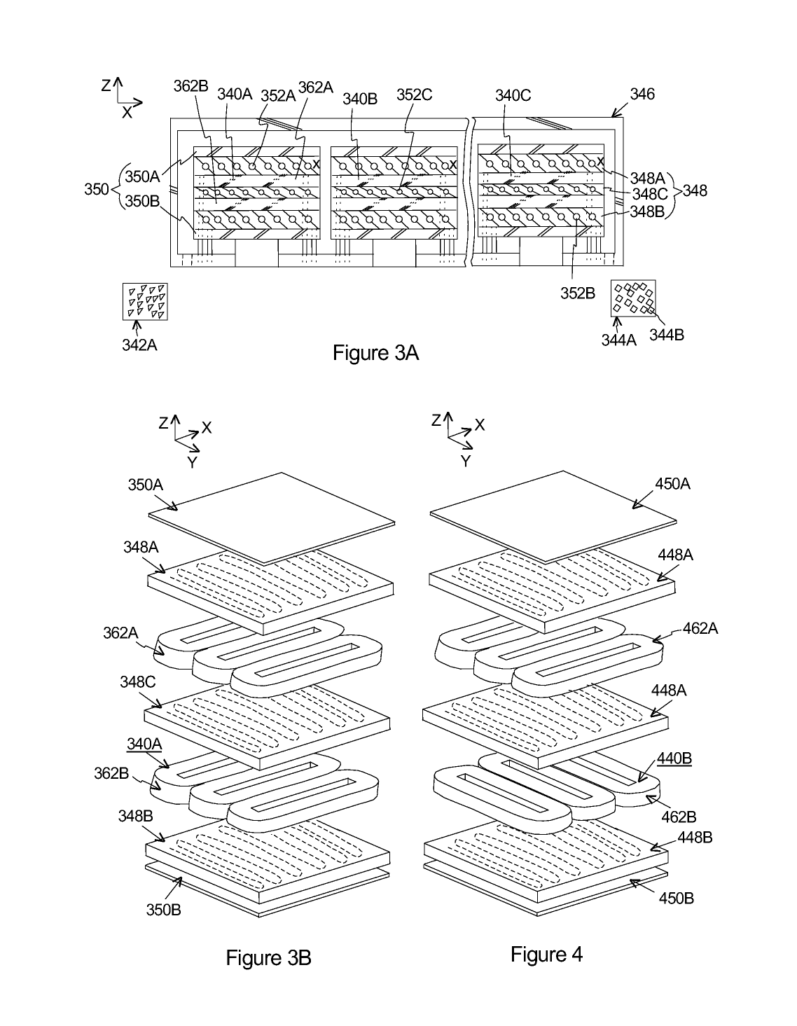

FIG. 3A is a cut-away view of yet another embodiment of (i) the conductor units, namely the first conductor unit 340A, the second conductor unit 340B, and the third conductor unit 340C; and (ii) the plate assembly 348. The insulation assembly 350, the circulation housing 346, and the fluid systems 342A, 344A are similar to the corresponding components described above and illustrated in FIG. 2A.

In FIG. 3A, each conductor unit 340A, 340B, 340C includes an upper coil set 362A and a lower coil set 362B that is spaced apart from the upper coil set 362A. Moreover, in this embodiment, for each conductor unit 340A, 340B, 340C, the plate assembly 348 includes (i) an upper, first plate 348A that is positioned above and adjacent to the upper coil set 362A, (ii) a lower, second plate 348B that is positioned below and adjacent to the lower coil set 362B, and (iii) an intermediate, third plate 348C that is positioned between and adjacent to the coil sets 362A, 362B. In this embodiment, each plate 348A, 348B, 348C is similar in design to the plates 248A, 248B described above and illustrated in FIGS. 2A-2C.

In FIG. 3A, (i) the first plate 348A includes one or more first plate channels 352A (illustrated with circles) that weave back and forth in the first plate 348A; (ii) the second plate 348B includes one or more second plate channels 352B (illustrated with circles) that weave back and forth in the third plate 348B; and (iii) the third plate 348C includes one or more third plate channels 352C (illustrated with circles) that weave back and forth in the third plate 348C. As with the embodiment shown in FIG. 2A, other configurations for the channels 352A, 352B, 352C, such as a straight-through channel may be preferable in some applications.

With this design, the second fluid system 344A directs the second circulation fluid 344B through the plates 348A, 348B, 348C to remove the bulk of the heat from the assembly.

FIG. 3B is an exploded perspective view of (i) the first conductor unit 340A including the upper, first coil set 362A and the lower, second coil set 362B; (ii) the upper, first plate 348A, (iii) the lower, second plate 348B; (iv) the intermediate, third plate 348C; (v) the upper, first insulator 350A; and (vi) the lower, second insulator 350B.

In this non-exclusive embodiment, each coil set 362A, 362B can also be referred to as a Y coil set because current directed to each coil set 362B is used to generate a force along the Y axis. Depending on the requirements of a particular application, other conductor units such as 340B, 340C could be configured as X coil sets by rotating the corresponding coil sets by 90° about the Z axis. Alternatively, for example, one or both of the coil sets 362A, 362B can be rotated ninety degrees and can be used to generate a force along the X axis.

Moving from the bottom to the top in FIG. 3B, the assembled components are as follows, (i) the bottom insulator 350B, (ii) the bottom plate 348B that is positioned on top of and in thermal contact with the bottom insulator 350B, (iii) the lower coil set 362B that is positioned on, adjacent to and in direct thermal contact with the bottom plate 348B, (iv) the intermediate plate 348C that is positioned on top of, adjacent to, and in direct thermal contact with the lower coil set 362B, (v) the upper coil set 362A that is positioned on, adjacent to, and in direct thermal contact with the intermediate plate 348C, (vi) the upper plate 348A that is positioned on top of, adjacent to, and in direct thermal contact with the upper coil set 362A, and (v) the upper insulator 350A that is position on top of and adjacent to the upper plate 348A.

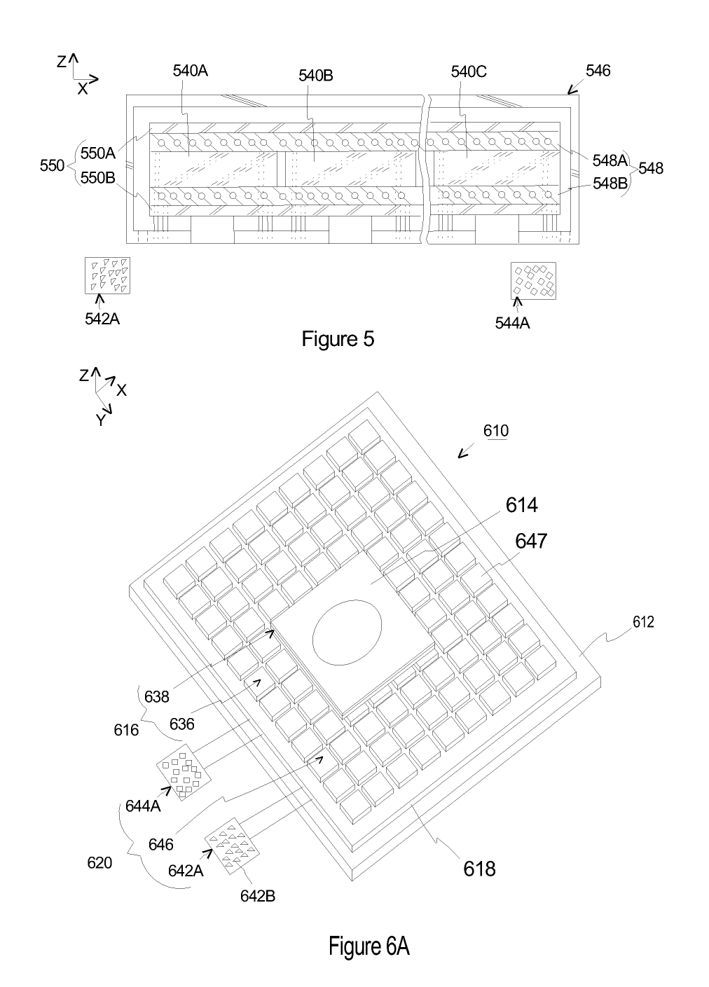

FIG. 4 is an exploded perspective view of another embodiment of the first conductor unit 440A including the upper, first coil set 462A and the lower, second coil set 462B. FIG. 4 also illustrates the upper, first plate 448A; the lower, second plate 448B; the intermediate, third plate 448C; the upper, first insulator 450A; and the lower, second insulator 450B that are similar to the corresponding components described above and illustrated in FIG. 3B.

In this non-exclusive embodiment, (i) the first coil set 462A is an X coil set because current directed to the first coil set 462A is used to generate a force along the X axis; (ii) the second coil set 462B is a Y coil set because current directed to the second coil set 462B is used to generate a force along the Y. Alternatively, the orientations of the coil sets 462A, 462B can be reversed.

Moving from the bottom to the top in FIG. 4, the assembled components are as follows, (i) the bottom insulator 450B, (ii) the bottom plate 448B that is positioned on top of the bottom insulator 450B, (iii) the lower coil set 462B that is positioned on, adjacent to and in direct thermal contact with the bottom plate 448B, (iv) the intermediate plate 448C that is positioned on top of, adjacent to, and in direct thermal contact with the lower coil set 462B, (v) the upper coil set 462A that is positioned on, adjacent to, and in direct thermal contact with the intermediate plate 448C, (vi) the upper plate 448A that is positioned on top of, adjacent to, and in direct thermal contact with the upper coil set 462A, and (v) the upper insulator 450A that is position on top of and adjacent to the upper plate 448A.

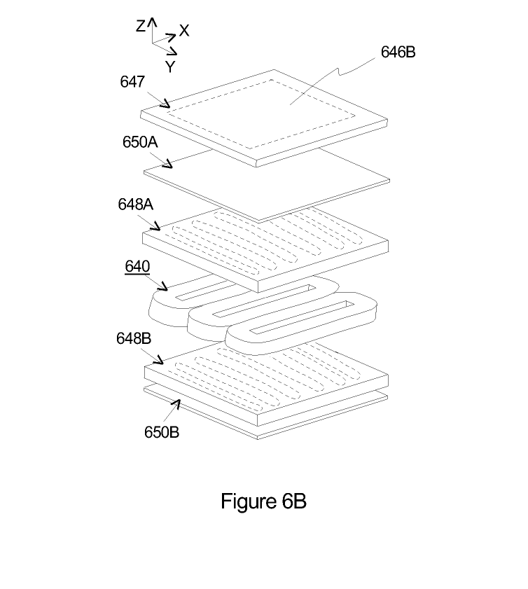

FIG. 5 is a cut-away view another embodiment of (i) the plate assembly 548 and the insulation assembly 550. In FIG. 5, the first conductor unit 540A, the second conductor unit 540B, and the third conductor unit 540C; the circulation housing 546; and the fluid systems 542A, 544A are similar to the corresponding components described above and illustrated in FIG. 2A.

In FIG. 5, in this embodiment, the plate assembly 548 includes (i) a single, upper, first plate 548A that is positioned above multiple conductor units 540A, 540B, 540C, (ii) a single, lower, second plate 548B that is positioned below multiple conductor units 540A, 540B, 540C. Further, the insulation assembly 550 includes (i) a single upper, first insulator 550A that is positioned above multiple conductor units 540A, 540B, 540C, (ii) a single, lower, second insulator 550B that is positioned below multiple conductor units 540A, 540B, 540C.

For example, each conductor unit 540A, 540B, 540C can include a single coil set, or multiple coil sets (as illustrated in FIGS. 3B and 4) with the plate assembly including an intermediate plate (as illustrated in FIGS. 3B and 4).

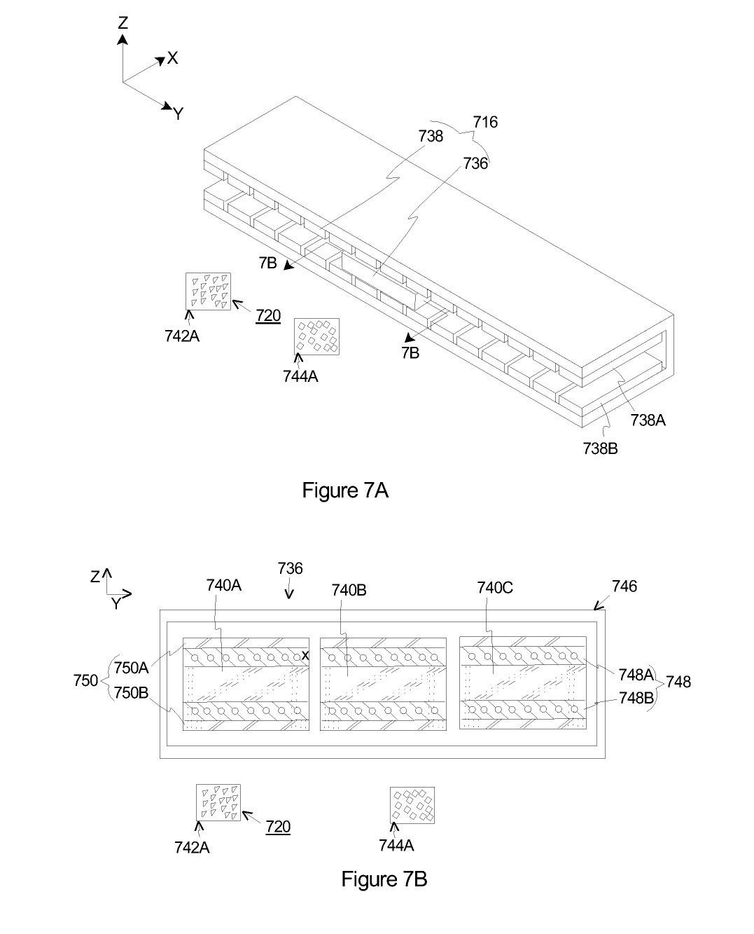

FIG. 6A illustrates another embodiment of a stage assembly 610 that includes a stage base 612, a stage 614, a stage mover 616 including the conductor array 636 and the magnet array 640, and a base assembly 618 that are somewhat similar to the corresponding components described above and illustrated in FIG. 1. However, in this embodiment, the temperature adjuster 620 is slightly different.

More specifically, in the embodiment, the temperature adjuster 620 includes (i) a first fluid system 642A (illustrated as a box), (ii) a second fluid system 644A (illustrated as a box), (iii) a plate assembly 648 (illustrated in FIG. 6B), and (iv) an insulation assembly 650 (illustrated in FIG. 6B) that are similar to the corresponding components described above. However, in this embodiment, the circulation housing 646 of the temperature adjuster 620 is different. More specifically, in this embodiment, the circulation housing 646 includes a separate surface housing 647 for each conductor unit 640 (illustrated in FIG. 6B), and the first fluid system 642A independently directs the first circulation fluid 642B into each surface housing 647.

FIG. 6B is an exploded perspective view that illustrates (i) a conductor unit 640, (ii) an upper, first plate 648A, (iv) a lower, second plate 648B; (v) the upper, first insulator 650A, and (vi) a lower, second insulator 650B that are similar to the corresponding components described above and illustrated in FIG. 2B. In this embodiment, the surface housing 647 is positioned over the top of and adjacent to the upper first insulator 650A. Further, the surface housing 647 is similar in profile to the upper first insulator 650A. In this embodiment, each surface housing 647 can define a separate housing passageway 646B (illustrated in phantom) in which the first circulation fluid 642B (illustrated in FIG. 6A) is circulated. Alternatively, the flow path of first circulation fluid 642B through surface housing 647 can be a serpentine path that weaves back and forth in the manner of the fluid path in plates 648A, 648B.

Alternatively, the surface housing 647 can sized to be positioned over multiple conductor units 640.

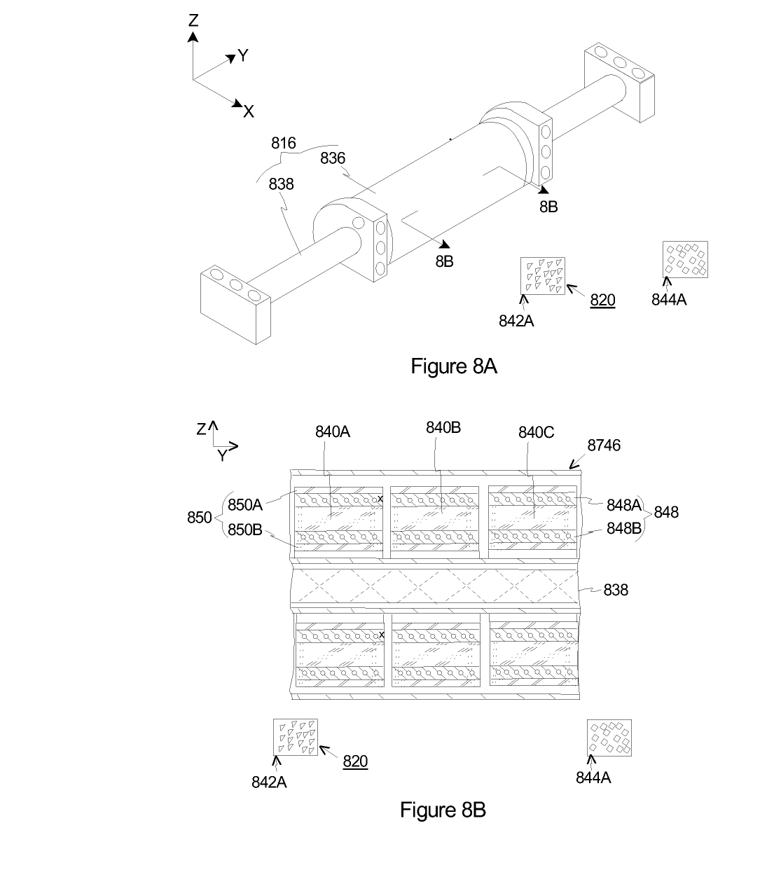

FIG. 7A illustrates another embodiment of a stage mover 716 and a temperature controller 720 including the fluid systems 742A, 744A. In this embodiment, the stage mover 716 is a linear mover (moves along the X axis) that includes a conductor array 736 and a magnet array 738. In this embodiment, the magnet array 738 includes an upper magnet set 738A and a lower magnet set 738B and the conductor array 736 is positioned between the magnet sets 738A, 738B. Each magnet set 738A, 738B includes a plurality of rectangular shaped magnets that are aligned side-by-side. The magnets in each magnet set 738A, 738B are orientated so that the poles alternate between the North pole and the South pole.

FIG. 7B is a cut-away view of the conductor array 736 taken on line 7B-7B in FIG. 7A. In this embodiment, the conductor array 736 includes three conductor units 740A, 740B, 740C that are similar to the conductor unit 240A illustrated in FIG. 2B. However, in this embodiment, all of the conductor units 740A, 740B, 740C are arranged in a linear array because this is a linear motor.

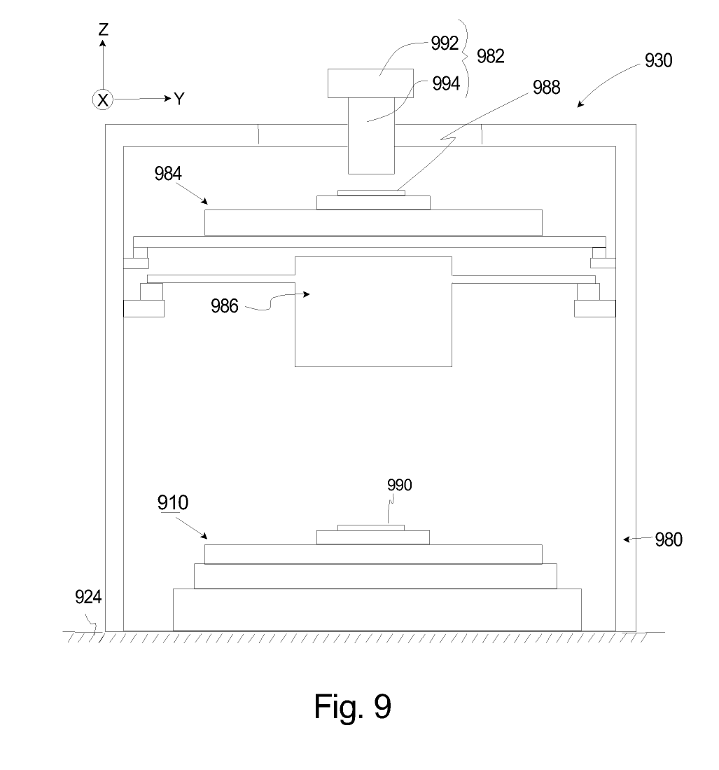

FIG. 8A illustrates yet another embodiment of a stage mover 816 and a temperature controller 820 including the fluid systems 842A, 844A. In this embodiment, the stage mover 816 is a shaft linear mover (moves along the X axis) that includes a conductor array 836 and a magnet array 838. In this embodiment, the magnet array 838 is positioned in a shaft that is encircled by the conductor array 836.

FIG. 8B is a cut-away view taken on line 8B-8B in FIG. 8A. In this embodiment, the conductor array 836 includes three, annular shaped conductor units 840A, 840B, 840C that are arranged in a linear array and that encircle the magnet array 838.

Further, in FIG. 8B, the temperature adjuster 820 includes (i) the first fluid system 842A (illustrated as a box), (ii) the second fluid system 844A (illustrated as a box), (iii) the plate assembly 848 including an annular shaped upper plate 848A and an annular shaped lower plate 848B, (iv) the insulation assembly 850 including an annular shaped upper insulator 850A, and an annular shaped lower insulator 850B, and (v) the circulation housing 846 is rectangular toroidal shaped and enclosed the other components.

As provided herein, the problem of removing heat from conductor array 836 without creating unacceptable thermal disturbances is solved by using high-pressure cold-plates 848A, 848B cooling and a high temperature rise to remove the majority of the heat from the conductor array 836, and surrounding the exterior of the cold-plates 848A, 848B with a low pressure circulation housing 846 (cooling jacket) to shield the exterior of the conductor array 836 from thermal disturbance caused by the large temperature rise.

In certain embodiments, the plate fluid removes the heat while the circulation fluid maintains the surface temperature.

It should also be noted that the present invention can be used in other types of actuators, such as a voice coil motor.

FIG. 9 is a schematic view illustrating an exposure apparatus 930 useful with the present invention. The exposure apparatus 930 includes the apparatus frame 980, an illumination system 982 (irradiation apparatus), a reticle stage assembly 984, an optical assembly 986 (lens assembly), and a wafer stage assembly 910. The stage assemblies provided herein can be used as the wafer stage assembly 910. Alternately, with the disclosure provided herein, the stage assemblies provided herein can be modified for use as the reticle stage assembly 784.

The exposure apparatus 930 is particularly useful as a lithographic device that transfers a pattern (not shown) of an integrated circuit from the reticle 988 onto the semiconductor wafer 990. The exposure apparatus 930 mounts to the mounting base 924, e.g., the ground, a base, or floor or some other supporting structure.

The apparatus frame 980 is rigid and supports the components of the exposure apparatus 930. The design of the apparatus frame 980 can be varied to suit the design requirements for the rest of the exposure apparatus 930.

The illumination system 982 includes an illumination source 992 and an illumination optical assembly 994. The illumination source 992 emits a beam (irradiation) of light energy. The illumination optical assembly 994 guides the beam of light energy from the illumination source 992 to the optical assembly 986. The beam illuminates selectively different portions of the reticle 788 and exposes the semiconductor wafer 990. In FIG. 9, the illumination source 992 is illustrated as being supported above the reticle stage assembly 984. Alternatively, the illumination source 992 can be secured to one of the sides of the apparatus frame 980 and the energy beam from the illumination source 992 is directed to above the reticle stage assembly 984 with the illumination optical assembly 994.

The optical assembly 986 projects and/or focuses the light passing through the reticle to the wafer. Depending upon the design of the exposure apparatus 930, the optical assembly 986 can magnify or reduce the image illuminated on the reticle.

The reticle stage assembly 984 holds and positions the reticle 988 relative to the optical assembly 986 and the wafer 990. Similarly, the wafer stage assembly 910 holds and positions the wafer 990 with respect to the projected image of the illuminated portions of the reticle 988.

There are a number of different types of lithographic devices. For example, the exposure apparatus 930 can be used as scanning type photolithography system that exposes the pattern from the reticle 988 onto the wafer 990 with the reticle 988 and the wafer 990 moving synchronously. Alternatively, the exposure apparatus 930 can be a step-and-repeat type photolithography system that exposes the reticle 988 while the reticle 988 and the wafer 990 are stationary.

However, the use of the exposure apparatus 930 and the stage assemblies provided herein are not limited to a photolithography system for semiconductor manufacturing. The exposure apparatus 930, for example, can be used as an LCD photolithography system that exposes a liquid crystal display device pattern onto a rectangular glass plate or a photolithography system for manufacturing a thin film magnetic head. Further, the present invention can also be applied to a proximity photolithography system that exposes a mask pattern by closely locating a mask and a substrate without the use of a lens assembly. Additionally, the present invention provided herein can be used in other devices, including other semiconductor processing equipment, elevators, machine tools, metal cutting machines, inspection machines and disk drives.

As described above, a photolithography system according to the above described embodiments can be built by assembling various subsystems, including each element listed in the appended claims, in such a manner that prescribed mechanical accuracy, electrical accuracy, and optical accuracy are maintained. In order to maintain the various accuracies, prior to and following assembly, every optical system is adjusted to achieve its optical accuracy. Similarly, every mechanical system and every electrical system are adjusted to achieve their respective mechanical and electrical accuracies. The process of assembling each subsystem into a photolithography system includes mechanical interfaces, electrical circuit wiring connections and air pressure plumbing connections between each subsystem. Needless to say, there is also a process where each subsystem is assembled prior to assembling a photolithography system from the various subsystems. Once a photolithography system is assembled using the various subsystems, a total adjustment is performed to make sure that accuracy is maintained in the complete photolithography system. Additionally, it is desirable to manufacture an exposure system in a clean room where the temperature and cleanliness are controlled.

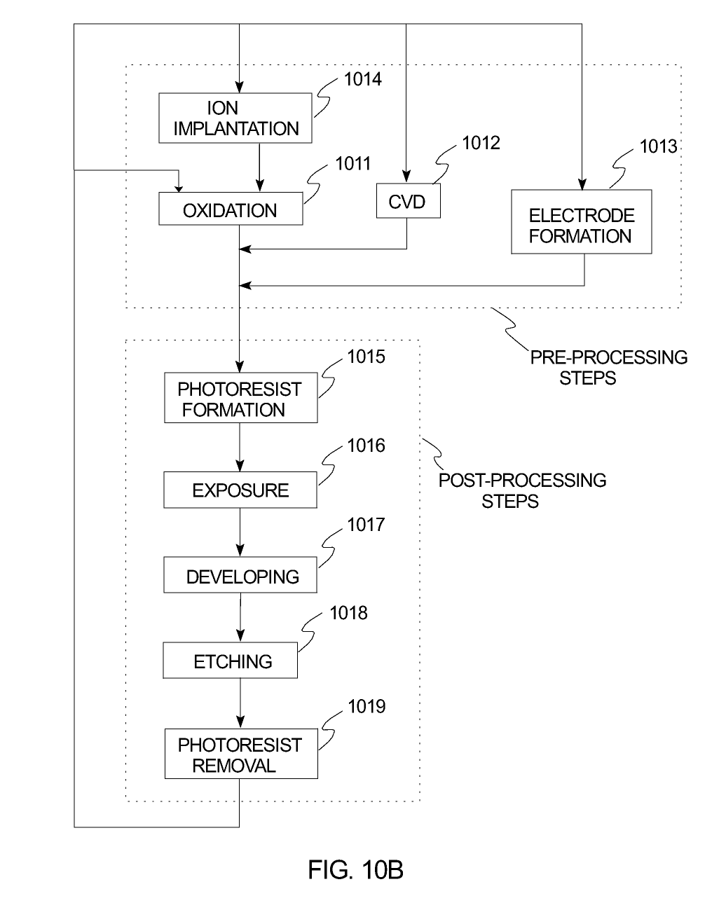

Further, semiconductor devices can be fabricated using the above described systems, by the process shown generally in FIG. 10A. In step 1001 the device's function and performance characteristics are designed. Next, in step 1002, a mask (reticle) having a pattern is designed according to the previous designing step, and in a parallel step 1003 a wafer is made from a silicon material. The mask pattern designed in step 1002 is exposed onto the wafer from step 1003 in step 1004 by a photolithography system described hereinabove in accordance with the present invention. In step 1005 the semiconductor device is assembled (including the dicing process, bonding process and packaging process), finally, the device is then inspected in step 1006.

FIG. 10B illustrates a detailed flowchart example of the above-mentioned step 1004 in the case of fabricating semiconductor devices. In FIG. 10B, in step 1011 (oxidation step), the wafer surface is oxidized. In step 1012 (CVD step), an insulation film is formed on the wafer surface. In step 1013 (electrode formation step), electrodes are formed on the wafer by vapor deposition. In step 1014 (ion implantation step), ions are implanted in the wafer. The above mentioned steps 1011-1014 form the preprocessing steps for wafers during wafer processing, and selection is made at each step according to processing requirements.

At each stage of wafer processing, when the above-mentioned preprocessing steps have been completed, the following post-processing steps are implemented. During post-processing, first, in step 1015 (photoresist formation step), photoresist is applied to a wafer. Next, in step 1016 (exposure step), the above-mentioned exposure device is used to transfer the circuit pattern of a mask (reticle) to a wafer. Then in step 1017 (developing step), the exposed wafer is developed, and in step 1018 (etching step), parts other than residual photoresist (exposed material surface) are removed by etching. In step 1019 (photoresist removal step), unnecessary photoresist remaining after etching is removed.

Multiple circuit patterns are formed by repetition of these preprocessing and post-processing steps.

While the particular stage assembly as shown and disclosed herein is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A stage assembly that moves a device, the stage assembly comprising:
a stage that retains the device;
a base assembly;
a stage mover that moves the stage, the stage mover including a magnet array that is secured to one of the stage and the base assembly, and a conductor array that is secured to the other of the stage and the base assembly, wherein current directed to the conductor array creates a force that can be used to move one of the arrays relative to the other array; and
a temperature adjuster that adjusts the temperature of at least a portion of the stage mover, the temperature adjuster including (i) a first plate that is positioned adjacent to a first side of the conductor array, the first plate defining a first plate channel, (ii) a first thermal insulator positioned adjacent to the first plate, (iii) a circulation housing that defines at least a portion of a housing passageway that is positioned adjacent to the first thermal insulator, the circulation housing including an outer surface; (iv) a first fluid system that directs a first circulation fluid through the housing passageway, and (v) a second fluid system that directs a second circulation fluid through the first plate channel; wherein the second circulation fluid removes the majority of the heat from the conductor array, and wherein the first circulation fluid shields the outer surface of the circulation housing from thermal disturbance.

2. The stage assembly of claim 1 further comprising a stage base, and wherein the base assembly includes a countermass that is supported by the stage base, wherein the base assembly moves relative to the stage base when a force is created to move one of the arrays relative to the other array.

3. The stage assembly of claim 1 wherein the circulation housing encircles the first plate, the first thermal insulator, and at least a portion of the conductor array.

4. The stage assembly of claim 1 wherein the temperature adjuster includes (i) a second plate positioned adjacent to a second side of the conductor array, the second plate defining a second plate channel, and (ii) a second thermal insulator positioned adjacent to the second plate; wherein the second fluid system directs the second circulation fluid through the second plate channel.

5. The stage assembly of claim 1 wherein the first plate channel includes a micro-channel having a cross-sectional area that is less than approximately five square millimeters.

6. The stage assembly of claim 1 wherein (i) the first fluid system directs the first circulation fluid into the housing passageway at a first fluid inlet temperature; (ii) the second fluid system directs the second circulation fluid into the first plate channel at a second fluid inlet temperature; and (iii) the first fluid inlet temperature is higher than the second fluid inlet temperature.

7. The stage assembly of claim 1 wherein the conductor array includes a first conductor unit and a second conductor unit, and wherein the temperature adjuster includes a separate first plate and a separate first thermal insulator for the first conductor unit and the second conductor unit.

8. The stage assembly of claim 7 wherein the circulation housing includes a separate surface housing for the first conductor unit and the second conductor unit.

9. The stage assembly of claim 1 wherein the stage mover is a planar motor and the conductor array includes a plurality of conductor units that are arranged in a rectangular grid.

10. The stage assembly of claim 1 wherein the stage mover is a linear motor and the conductor array includes a plurality of conductor units that are arranged in a linear array.

11. An exposure apparatus for transferring an image from a reticle to a device, the exposure apparatus comprising: an illumination system that directs an illumination beam at the reticle, and stage assembly of claim 1 moving one of the reticle and the device.

12. A process for manufacturing a device, the process comprising the steps of providing a substrate, and transferring an image to the device with the exposure apparatus of claim 11.

13. A stage assembly that moves a device, the stage assembly comprising:
a stage that retains the device;
a base assembly;
a stage mover that moves the stage, the stage mover including a magnet array that is secured to one of the stage and the base assembly, and a conductor array that is secured to the other of the stage and the base assembly, wherein current directed to the conductor array creates a force that can be used to move one of the arrays relative to the other array; and
a temperature adjuster that adjusts the temperature of at least a portion of the stage mover, the temperature adjuster including (i) a first plate that is positioned adjacent to a first side of the conductor array, the first plate defining a first plate micro-channel, (ii) a first thermal insulator positioned adjacent to the first plate, (iii) a second plate that is positioned adjacent to a second side of the conductor array, the second plate defining a second plate micro-channel, (iv) a second thermal insulator positioned adjacent to the second plate, (v) a circulation housing that defines at least a portion of a housing passageway that encircles the first plate, the first thermal insulator, and at least a portion of the conductor array, the circulation housing including an outer surface; (vi) a first fluid system that directs a first circulation fluid through the housing passageway, and (v) a second fluid system that directs a second circulation fluid through the first plate micro-channel and the second plate micro-channel; wherein the second circulation fluid removes the majority of the heat from the conductor array, and wherein the first circulation fluid shields the outer surface of the circulation housing from thermal disturbance.

14. The stage assembly of claim 13 wherein each plate channel has a cross-sectional area that is less than approximately five square millimeters.

15. The stage assembly of claim 13 wherein the conductor array includes a first conductor unit and a second conductor unit, and wherein the temperature adjuster includes a separate first plate and a separate first thermal insulator for the first conductor unit and the second conductor unit.

16. The stage assembly of claim 13 wherein the stage mover is a linear motor and the conductor array includes a plurality of conductor units that are arranged in a linear array.

17. The stage assembly of claim 13 wherein the stage mover is a planar motor and the conductor array includes a plurality of conductor units that are arranged in a rectangular grid.

18. An exposure apparatus for transferring an image from a reticle to a device, the exposure apparatus comprising: an illumination system that directs an illumination beam at the reticle, and stage assembly of claim 17 moving one of the reticle and the device.

19. A process for manufacturing a device, the process comprising the steps of providing a substrate, and transferring an image to the device with the exposure apparatus of claim 18.

20. A method for moving a device, the method comprising the steps of:
retaining the device with a stage;
providing a base assembly;
moving the stage with a stage mover that includes a magnet array that is secured to one of the stage and the base assembly, and a conductor array that is secured to the other of the stage and the base assembly, wherein current directed to the conductor array creates a force that can be used to move one of the arrays relative to the other array; and
adjusting the temperature of at least a portion of the stage mover with a temperature adjuster that includes (i) a first plate that is positioned adjacent to a first side of the conductor array, the first plate defining a first plate channel, (ii) a first thermal insulator positioned adjacent to the first plate, (iii) a circulation housing that defines at least a portion of a housing passageway that is positioned adjacent to the first thermal insulator, the circulation housing including an outer surface; (iv) a first fluid system that directs a first circulation fluid through the housing passageway, and (v) a second fluid system that directs a second circulation fluid through the first plate channel; wherein the second circulation fluid removes the majority of the heat from the conductor array, and wherein the first circulation fluid shields the outer surface of the circulation housing from thermal disturbance.
